(19) United States
(12) Patent Application Publication
(10) Pub. No.: US 2026/0231481 A1
(43) Pub. Date: Aug. 6, 2026

(54) POWER SEMICONDUCTOR DEVICE

(71) Applicant: HYUNDAI MOBIS CO., LTD., Seoul (KR)

(72) Inventors: Kang Min GI, Yongin-si (KR); Lee Jeong YUN, Yongin-si (KR); Lee Ju HWAN, Yongin-si (KR); Hwang Jun HA, Yongin-si (KR); Ha Jung MOK, Yongin-si (KR); Kim Sin A, Yongin-si (KR); Kang Mi AE, Yongin-si (KR); You Bo LIM, Yongin-si (KR)

(73) Assignee: HYUNDAI MOBIS CO., LTD., Seoul (KR)

(21) Appl. No.: 19/364,027

(22) Filed: Oct. 21, 2025

(30) Foreign Application Priority Data
Jan. 31, 2025 (KR) 10-2025-0012301
Mar. 28, 2025 (KR) 10-2025-0040063

(51) Int. Cl. H10D 62/10; H10D 30/66; H10D 62/832; H10D 64/27

(52) U.S. Cl. CPC H10D 62/107; H10D 30/668; H10D 62/8325; H10D 64/513

(57) ABSTRACT

According to one embodiment, there is provided a power semiconductor device including a first electrode, a semiconductor layer on the first electrode, a second electrode on the semiconductor layer, and a plurality of gate electrodes on the semiconductor layer, wherein the semiconductor layer includes a first semiconductor layer of a first conductivity type on the first electrode, and a second semiconductor layer of a second conductivity type between the first semiconductor layer and the second electrode, the second semiconductor layer includes a 3-1 layer extending in a first direction, and a plurality of 3-2 layers spaced apart from each other in a second direction intersecting the first direction and spaced apart from the 3-1 layer in the second direction, the first semiconductor layer or the second semiconductor layer includes a trench region, the trench region is disposed around the plurality of 3-2 layers, the gate electrodes are disposed in the trench region, and the gate electrods are disposed between the adjacent 3-1 and 3-2 layers and between a plurality of adjacent 3-2 layers.

### CROSS REFERENCE TO RELATED APPLICATION

This patent document claims priority to Korean Patent Application No. 10-2025-0012301, filed Jan. 31, 2025, and also Korean Patent Application No. 10-2025-0040063, filed Mar. 28, 2025, the disclosure of which is incorporated herein for all purposes by this reference.

### TECHNICAL FIELD

Embodiments of the disclosed technology relate to a power semiconductor device.

### BACKGROUND

Power semiconductor devices are semiconductor devices that operate in high voltage and high current environments. The power semiconductor devices are used in fields that require high power switching, such as power conversion, power converters, inverters, etc. For example, the power semiconductor device may include insulated gate bipolar transistors (IGBTs), power metal oxide semiconductor field effect transistors (MOSFETs), etc. The power semiconductor devices basically require high voltage withstand characteristics, and recently, have additionally required a high-speed switching operation.

Accordingly, power semiconductor devices using silicon carbide (SiC) instead of existing silicon (Si) are being studied. Silicon carbide (SiC) is a wide-gap semiconductor material with a higher bandgap than silicon and can maintain stability even at high temperatures compared to silicon. Furthermore, silicon carbide has a much higher breakdown voltage than silicon, and thus can operate stably even at high voltages. Accordingly, silicon carbide has a higher breakdown voltage than silicon and also has excellent heat dissipation, thereby exhibiting operable characteristics at high temperatures.

### SUMMARY

Embodiments of the present specification are directed to providing a power semiconductor device capable of improving the electrical and physical stability of a lower portion of a gate.

Embodiments of the present specification are directed to providing a power semiconductor device capable of reducing energy loss by minimizing an increase in resistance.

Objects of the present specification are not limited to the above-described objects, and other technical objects may be inferred from the following embodiments.

In order to achieve the above objects, according to one embodiment, there is provided a power semiconductor device including a first electrode, a semiconductor layer on the first electrode, a second electrode on the semiconductor layer, and a plurality of gate electrodes on the semiconductor layer, wherein the semiconductor layer includes a first semiconductor layer of a first conductivity type on the first electrode, and a second semiconductor layer of a second conductivity type between the first semiconductor layer and the second electrode, the second semiconductor layer includes a 3-1 layer extending in a first direction, and a plurality of 3-2 layers spaced apart from each other in a second direction intersecting the first direction and spaced apart from the 3-1 layer in the second direction, the first semiconductor layer or the second semiconductor layer includes a trench region, the trench region is disposed around the plurality of 3-2 layers, the gate electrodes are disposed in the trench region, and the gate electrodes are disposed between the adjacent 3-1 and 3-2 layers and between a plurality of adjacent 3-2 layers.

Detailed matters of other embodiments are included in the detailed description and accompanying drawings.

### BRIEF DESCRIPTION OF THE DRAWINGS

FIG. 1 is a view of a power semiconductor device according to one embodiment.

FIG. 2 is a view showing a semiconductor layer of FIG. 1.

FIG. 3 is a view showing a flow of electrons in the semiconductor layer of FIG. 2.

FIG. 4 is a view showing a second electrode of FIG. 1.

FIG. 5 is a cross-sectional view showing region Q1 of FIG. 1.

FIG. 6 is a plan view of the power semiconductor device according to one embodiment.

FIG. 7 is a view showing a semiconductor layer of a power semiconductor device according to another embodiment.

FIG. 8 is a view showing a power semiconductor device according to still another embodiment.

FIG. 9 is a cross-sectional view showing region Q2 of FIG. 8.

FIG. 10 is a view showing a power semiconductor device according to yet another embodiment.

FIG. 11 is a cross-sectional view showing region Q3 of FIG. 10.

### DETAILED DESCRIPTION OF THE DISCLOSURE

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the specification, when a certain component (or a region, a layer, a portion, etc.) is described as “on,” “connected,” or “coupled to” another component, it means that the certain component may be directly connected/coupled to another component or still another component may be disposed therebetween.

The term “and/or” includes all one or more combinations that may be defined by the associated configurations.

The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation with one element or components and another element or components as shown in the drawings. The spatially relative terms should be understood as including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification may be coupled or combined partially or entirely, various technological interworking and driving are made possible, and the embodiments may be implemented independently of each other or implemented together in an associated relationship.

Hereinafter, a power semiconductor device of the present specification will be described with reference to the accompanying drawings and embodiments as follows.

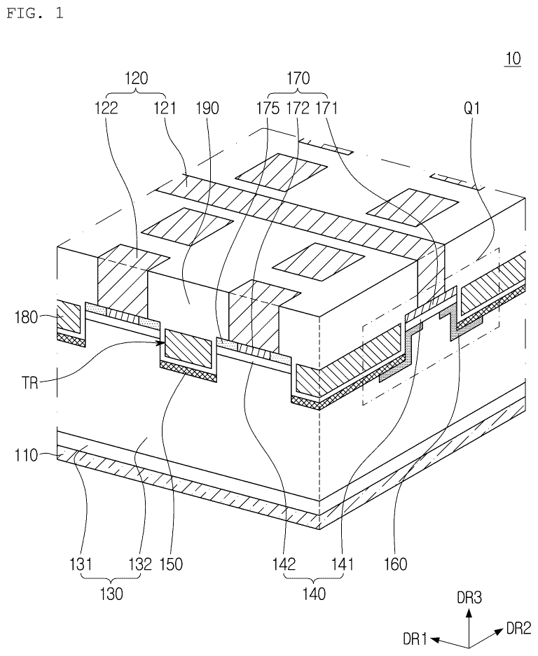

FIG. 1 is a view of a power semiconductor device according to one embodiment.

Referring to FIG. 1, a power semiconductor device according to one embodiment may include a first electrode 110, a second electrode 120 facing the first electrode 110, and a plurality of components 130, 140, 150, 160, 170, 180, 190, and TR between the first electrode 110 and the second electrode 120.

A portion of the power semiconductor device is shown in FIG. 1, but a plurality of power semiconductor devices may be disposed.

The first electrode 110 may be a drain electrode, and the second electrode 120 may be a source electrode, but embodiments of the present specification are not limited thereto, and the two electrodes may be opposite to each other. The first electrode 110 and the second electrode 120 may include a conductive material. For example, the conductive material may be a metal, but the embodiments of the present specification are not limited thereto.

The second electrode 120 may include a 2-1 electrode 121 and a 2-2 electrode 122. The 2-1 electrode 121 may extend in a first direction DR1, the 2-2 electrode 122 may be provided as a plurality of electrodes, and the plurality of 2-2 electrodes 122 may be disposed to be spaced apart from each other in the first direction DR1 and a second direction DR2. The 2-1 electrode 121 may be provided as a plurality of electrodes, and the plurality of 2-2 electrodes 122 may be disposed between the plurality of 2-1 electrodes 121.

The 2-1 electrode 121 may be in direct contact with a 1-1 source layer 171. The 2-1 electrode 121 may be surrounded by an insulating layer 190, but a lower portion thereof may be exposed. The 2-1 electrode 121 may be in direct contact with the 1-1 source layer 171 through the exposed lower portion.

The 2-2 electrode 122 may be in direct contact with a 1-2 source layer 172 and a second source layer 175. The 2-2 electrode 122 may be surrounded by an insulating layer 190, but a lower portion thereof may be exposed. The 2-2 electrode 121 may be in direct contact with the 1-2 source layer 172 and the second source layer 175 through the exposed lower portion. Current may flow through a region in which the 2-2 electrode 122 is in direct contact with the second source layer 175. In a cross-section in which the first direction DR1 and a third direction DR3 intersect, two second source layers 175 may be disposed between adjacent gate electrodes 180, and one 1-2 source layer 172 may be disposed between two second source layers 175, but various embodiments of the present specification are not limited thereto.

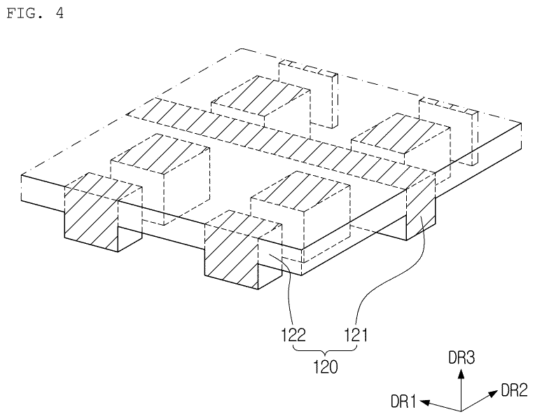

In the view, the 2-1 electrode 121 and the 2-2 electrode 122 are shown as being spaced apart from each other, but the 2-1 electrode 121 and the 2-2 electrode 122 may be electrically connected. This will be described below in FIG. 4. Thicknesses of the 2-1 electrode 121 and the 2-2 electrode 122 may be the same, but the embodiments of the present specification are not limited thereto.

Semiconductor layers 130, 140, 150, 160, and 170 between the first electrode 110 and the second electrode 120 may include silicon carbide (SiC) and have different conductivity types or different doping concentrations. Silicon carbide (SiC) may have high withstand voltage characteristics. The semiconductor layers 130, 140, 150, 160, and 170 may include a first semiconductor layer 130, a second semiconductor layer 140 on the first semiconductor layer 130, a source layer 170 on the second semiconductor layer, a protective layer 150 disposed between the first semiconductor layer 130 and the second semiconductor layer 140, and a bonding layer 160.

The first semiconductor layer 130 may be disposed on the first electrode 110. The first semiconductor layer 130 may include a first layer 131 and a second layer 132. The first layer 131 may be directly disposed on the first electrode 110, and the second layer 132 may be directly disposed on the first layer 131. The first semiconductor layer 130 may have a first conductivity type, and the first conductivity type may be N-type.

The doping concentration of the first layer 131 may be higher than the doping concentration of the second layer 132. Since the doping concentration of the first layer 131 is higher than the doping concentration of the second layer 132, a junction resistance between the first electrode 110 and the first semiconductor layer 130 can be reduced.

The second layer 132 may be disposed between adjacent gate electrodes 180. That is, the second layer 132 may be located on the first layer 131 and may have a shape that protrudes upward (e.g., in the third direction DR3) in a region in which the gate electrode 180 is not disposed.

The second semiconductor layer 140 may have a second conductivity type, and the second conductivity type may be P-type. The second semiconductor layer 140 may include a 3-1 layer 141 and a 3-2 layer 142.

The second semiconductor layer 140 may be disposed on the second layer 132. In a plan view, the 3-1 layer 141 may be located under the 2-1 electrode 121, and the 3-2 layer 142 may be located under the 2-2 electrode 122.

The bonding layer 160 may be disposed between the 3-1 layer 141 and the second layer 132, and the 3-1 layer 141 may be in direct contact with the bonding layer 160. In a region in which the bonding layer 160 is not disposed, the 3-1 layer 141 may be in direct contact with the second layer 132. The 1-1 source layer 171 may be disposed on the 3-1 layer 141. The 3-1 layer 141 may be in direct contact with the 1-1 source layer 171. The 3-1 layer 141 may extend in the first direction DR1, and the 1-1 source layer 171 disposed on the 3-1 layer 141 may also extend in the first direction DR1. The extended 3-1 layer 141 and 1-1 source layer 171 may have the same area in a plan view viewed from the top to the bottom. That is, widths of the 3-1 layer 141 and the 1-1 source layer 171 in the first direction DR1 and the second direction DR2 may be the same. However, the embodiments of the present specification are not limited thereto.

The 1-2 source layer 172 and the second source layer 175 may be disposed on the 3-2 layer 142, an upper surface of the 3-2 layer 142 may be in direct contact with each of the 1-2 source layer 172 and the second source layer 175, and a lower surface of the 3-2 layer 142 may be in direct contact with the second layer 132. Current may flow through a region in which the 3-2 layer 142 is in direct contact with the second source layer 175.

The 3-2 layer 142 may be provided as a plurality of layers, and the plurality of 3-2 layers 142 may be disposed to be spaced apart in each of the first direction DR1 and the second direction DR2. The plurality of 3-2 layers 142 spaced apart in the first direction DR1 and the second direction DR2 may be disposed between the plurality of 3-1 layers 141 that extend in the first direction DR1. That is, the plurality of 3-2 layers 142 spaced apart from each other may be disposed symmetrically with respect to the 3-1 layer 141 and disposed to be spaced apart from each other in the second direction DR2. That is, the 3-1 layer 141 may have a line shape, but the 3-2 layer 142 may have an island (or dot) shape. Accordingly, side surfaces of the 3-1 layer 141 and side surfaces of the 3-2 layer 142 may be exposed in the separated space.

The exposed side surfaces of the 3-1 layer 141 and the 3-2 layer 142 may be in direct contact with the insulating layer 190. The insulating layer 190 may insulate the second semiconductor layer 140 and the gate electrode 180.

The source layer 170 may be disposed on the second semiconductor layer 140. The source layer 170 may include the 1-1 source layer 171 disposed on the 3-1 layer 141, the 1-2 source layer 172 disposed on the 3-2 layer 142, and the second source layer 175 disposed on the 3-2 layer 142.

The 1-1 source layer 171 and the 1-2 source layer 172 may have a second conductivity type, and the second conductivity type may be P-type. The doping concentrations of the 1-1 source layer 171 and the 1-2 source layer 172 may be higher than the doping concentration of the second semiconductor layer 140. Since the doping concentrations of the 1-1 source layer 171 and the 1-2 source layer 172 is higher than the doping concentration of the second semiconductor layer 140, contact resistance at a contact surface with the second electrode 120 can be reduced.

A lower portion of the 1-1 source layer 171 may be in direct contact with the 3-1 layer 141, an upper portion thereof may in direct contact with the 2-1 electrode 121, and side surfaces thereof may be in direct contact with the insulating layer 190.

A lower portion of the 1-2 source layer 172 may be in direct contact with the 3-2 layer 142, an upper portion thereof may in direct contact with the 2-2 electrode 122, and side surfaces thereof may be in direct contact with the second source layer 175 and/or the insulating layer 190.

In a plan view viewed from the top to the bottom, an area of the 1-2 source layer 172 may be smaller than an area of the 3-2 layer 142. In FIG. 1, the 1-2 source layer 172 is shown as being located on a central portion of the 3-2 layer 142 in the first direction DR1, but the embodiments of the present specification are not limited thereto. For example, the 1-2 source layer 172 may be disposed on an edge of the 3-2 layer 142.

The second source layer 175 may have a first conductivity type, and the first conductivity type may be N-type. The doping concentration of the second source layer 175 may be higher than the doping concentration of the second layer 132.

A lower portion of the second source layer 175 may be in direct contact with the 3-2 layer 142, an upper portion thereof may in direct contact with the 2-2 electrode 122 and the insulating layer 190, and side surfaces thereof may be in direct contact with the 1-2 source layer 172 and/or the insulating layer 190.

In a plan viewed from the top to the bottom, the second source layer 175 may be disposed in a shape that surrounds the 1-2 source layer 172. Furthermore, the second source layer 175 may be disposed in a shape that completely surrounds the 1-2 source layer 172. However, the embodiments of the present specification are not limited thereto. That is, the second source layer 175 may be disposed in a shape that surrounds only at least one surface of the 1-2 source layer 172.

The protective layer 150 has a second conductivity type, and the second conductivity type may be P-type. The doping concentration of the protective layer 150 may be higher than the doping concentration of the second semiconductor layer 140.

The protective layer 150 may be disposed between the second layer 132 and the gate electrode 180. A lower surface and side surfaces of the protective layer 150 may be in direct contact with the second layer 132, and an upper surface thereof may be in direct contact with the gate electrode 180 or the insulating layer 190 surrounding the gate electrode 180.

The bonding layer 160 has a second conductivity type, and the second conductivity type may be P-type. The doping concentration of the bonding layer 160 may be higher than the doping concentration of the second semiconductor layer 140, but the embodiments of the present specification are not limited thereto.

The bonding layer 160 may be disposed between the second layer 132 and the 3-1 layer 141 and/or the protective layer 150 and may be in direct contact with adjacent components 132, 141, and 150. For example, the bonding layer 160 may be disposed in a form that overlaps both the lower portion of the protective layer 150 and the lower portion of the 3-1 layer 141, disposed in a form that is in contact with only the lower portion of the 3-1 layer 141, or disposed in a form that is in contact with only the lower portion of the protective layer 150. The bonding layer 160 may also be disposed between side surfaces of a trench region TR and the second layer 132. That is, the bonding layer 160 may also be disposed between the side surfaces of the insulating layer 190 surrounding the trench region TR and the second layer 132. For example, in a plan view formed by the second direction DR2 and the third direction DR3, a cross-sectional shape of the bonding layer 160 may be an ohm (Ω) shape, but the embodiments of the present specification are not limited thereto.

In a plan view (when viewed from the top to the bottom), the gate electrode 180 may be disposed around the plurality of 2-2 electrodes 122 spaced apart from each other. For example, the gate electrode 180 may be provided as a plurality of electrodes, and the plurality of gate electrodes 180 may be disposed in a form that surrounds the 2-2 electrodes 122 spaced apart from each other in the first direction DR1 and the second direction DR2 from all sides. The plurality of gate electrodes 180 may be electrically connected. That is, the plurality of gate electrodes 180 may be electrically connected in a grid form. In addition, the plurality of gate electrodes 180 connected in a grid form may be disposed symmetrically with the 2-1 electrode 121 interposed therebetween and disposed to be spaced apart from each other in the second direction DR2.

The second layer 132, the 3-2 layer 142, the 1-2 source layer 172, and the second source layer 175 may be disposed between the plurality of gate electrodes 180 spaced apart from each other in the first direction DR1, and the second layer 132, the bonding layer 160, the 3-1 layer 141, and the 1-1 source layer 171 may be disposed between the plurality of gate electrodes 180 spaced apart from each other in the second direction DR2. The gate electrode 180 may be completely surrounded by the insulating layer 190. That is, the insulating layer 190 may insulate the gate electrode 180 and the plurality of components 132, 141, 142, 160, 171, 172, and 175.

The gate electrode 180 may include a conductive material. For example, the conductive material may be a metal or poly silicon, but the embodiments of the present specification are not limited thereto.

The insulating layer 190 may insulate a semiconductor layer adjacent to the gate electrode 180 and insulate the plurality of second electrodes 120. Examples of the insulating layer 190 may include silicon oxide (SiO₂), silicon nitride (SiNₓ), silicon oxynitride (SiON), etc., but the embodiments of the present specification are not limited thereto.

A plurality of trench regions TR may be formed in the plurality of components 130, 140, and 170 between the first electrode 110 and the second electrode 120. The trench regions TR may be disposed around the 2-2 electrode 122 in a plan view and provided as a plurality of regions. The plurality of trench regions TR may be spaced apart from each other in the first direction DR1 and the second direction DR2 and disposed side by side and connected to form a grid form. The plurality of trench regions TR connected in the grid form may be disposed to be symmetrically spaced apart from each other with the 2-1 electrode 121 interposed therebetween. The gate electrode 180 may be disposed within the trench region TR.

The trench region TR may recess the second layer 132, the second semiconductor layer 140, the source layer 170, and the insulating layer 190 in a thickness direction. The protective layer 150 may be disposed under the trench region TR. A width of the protective layer 150 may be the same as a width of the trench region TR. However, the embodiments of the present specification are not limited thereto, and the protective layer 150 may cover a portion of a side portion of the trench region TR.

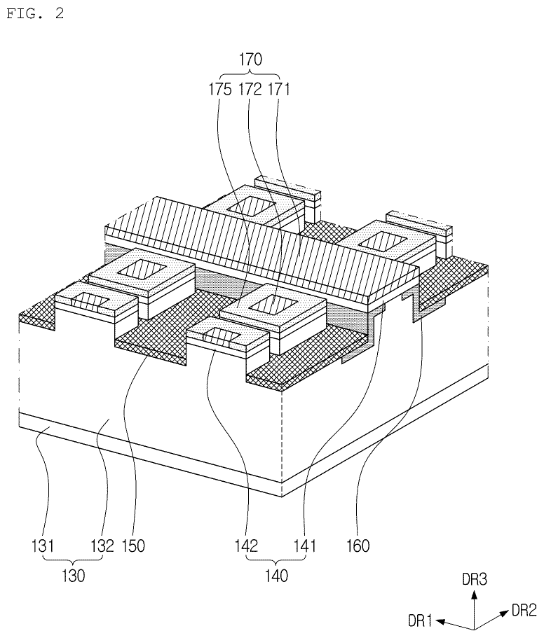

FIG. 2 is a view showing a semiconductor layer of FIG. 1.

FIG. 2 is a view showing the components 130, 140, 150, 160, and 170 of the semiconductor layer formed between the first electrode 110 (see FIG. 1) and the insulating layer 190 (see FIG. 1) and is introduced to describe an internal structure of the semiconductor layers 130, 140, 150, 160, and 170.

Referring to FIG. 2, the 1-1 source layer 171 may extend in the first direction DR1, the 1-2 source layer 172 and the second source layer 175 may be provided as a plurality of layers, and the plurality of 1-2 source layers 172 and the second source layers 175 may be disposed to be spaced apart from each other in the first direction DR1 and the second direction DR2. That is, the 1-2 source layer 172 and the second source layer 175 may have an island (or dot) shape. The 1-1 source layer 171 may be provided as a plurality of layers, and the plurality of 1-2 source layers 172 and second source layers 175 may be disposed between the plurality of 1-1 source layers 171.

The thicknesses of the 1-1 source layer 171, the 1-2 source layer 172, and the second source layer 175 may be the same, but the embodiments of the present specification are not limited thereto.

The second source layer 175 may be disposed in a form that surrounds the 1-2 source layer 172 from all sides. Accordingly, an area in which an upper surface of the second source layer 175 is in direct contact with the 2-2 electrode 125 (see FIG. 1) may be formed in a form that surrounds the 1-2 source layer 172 from all sides, and current may also flow through the area in a form that surrounds the 1-2 source layer 172 from all sides. However, the embodiments of the present specification are not limited thereto.

In a plan view, the protective layer 150 may be disposed between the plurality of 1-2 source layers 172 and second source layers 175 spaced apart from each other and may also be disposed between the 1-1 source layer 171, the 1-2 source layer 172, and the second source layer 175 that are spaced apart from each other in the first direction DR1.

The bonding layer 160 may perform a function of electrically connecting the 3-1 layer 141 to the protective layer 150. As the 1-1 source layer 171, the 3-1 layer 141, the bonding layer 160, and the protective layer 150 are electrically connected, an electric field under the protective layer 150 can be stabilized.

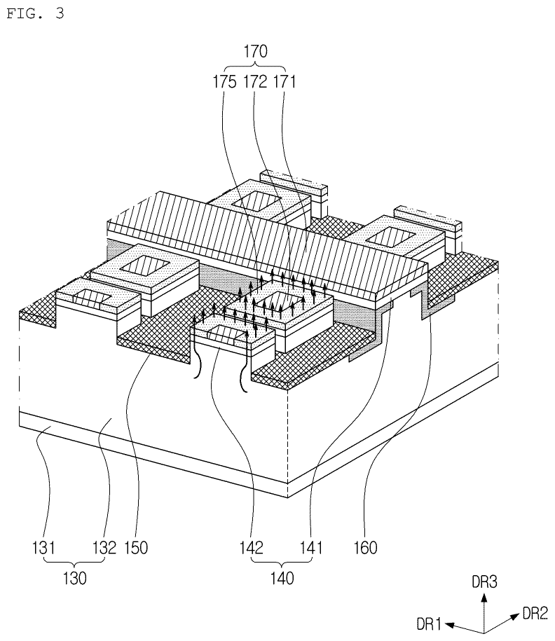

FIG. 3 is a view showing a flow of electrons in the semiconductor layer of FIG. 2.

Referring to FIG. 3, depending on a voltage applied to the gate electrode 180 (see FIG. 1), a channel may be formed along side surfaces where the gate electrode 180 (see FIG. 1) and the 3-2 layer 142 are in contact. For example, when a positive voltage higher than a threshold voltage (VTH) is applied to the gate electrode 180 (see FIG. 1), a channel may be formed in the 3-2 layer 142 around the gate electrode 180 (see FIG. 1).

Electrons may move from the first electrode 110 (see FIG. 1) to the second source layer 175 through the channel formed by the 3-2 layer 142 and the gate electrode 180 (see FIG. 1). Since the second source layer 175 may be in direct contact with the 2-2 electrode 122, current may eventually flow between the first electrode 110 (see FIG. 1) and the second electrode 120.

FIG. 4 is a view showing a second electrode of FIG. 1.

Referring to FIG. 4, the second electrode 120 may include the 2-1 electrode 121 extending in the second direction DR2 and the plurality of 2-2 electrodes 122 spaced apart from each other in the first direction DR1 and the second direction DR2.

A separate conductive layer may be disposed on the 2-1 electrode 121 and the 2-2 electrode 122, and the 2-1 electrode 121 and the 2-2 electrode 122 may be electrically connected through the conductive layer to form one second electrode.

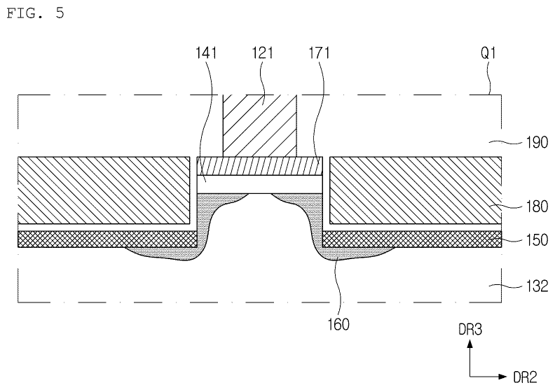

FIG. 5 is a cross-sectional view showing region Q1 of FIG. 1.

Referring to FIG. 5, the bonding layer 160 may perform a function of electrically connecting the 3-1 layer 141 to the protective layer 150. The bonding layer 160 may be in direct contact with a lower portion of the 3-1 layer 141 and may also be in direct contact with a lower portion and/or side surfaces of the protective layer 160.

For example, the bonding layer 160 may be in direct contact with a portion of the lower portion of the 3-1 layer 141 and at the same time, may be in direct contact with only the side surface of the protective layer 150, and may be in direct contact with a portion of the lower portion of the 3-1 layer 141 and at the same time, may be in direct contact with the side surfaces and lower surface of the protective layer 150.

The bonding layer 160 may be provided as a plurality of bonding layers, and the plurality of bonding layers 160 may be disposed to be in direct contact with each of the plurality of protective layers 150 spaced apart from each other in the second direction DR2. The plurality of bonding layers 160 may be in direct contact with each other, but may not be in direct contact with each other.

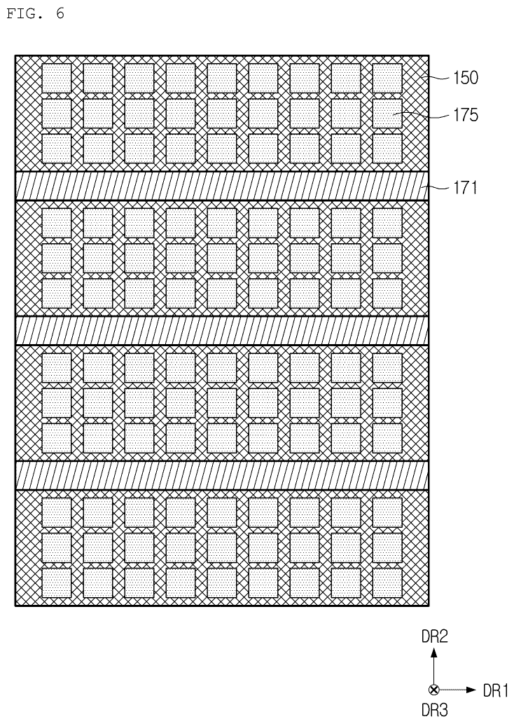

FIG. 6 is a plan view of the power semiconductor device according to one embodiment.

Referring to FIG. 6, the plurality of 1-1 source layers 171 extending in the first direction DR1 may be disposed to be spaced apart from each other in the second direction DR2. The second source layers 175 spaced apart from each other in the first direction DR1 and the second direction DR2 may be disposed between the plurality of 1-1 source layers 171. The protective layer 150 may be disposed between the separated 1-1 source layers 171, the separated second source layers 175, etc.

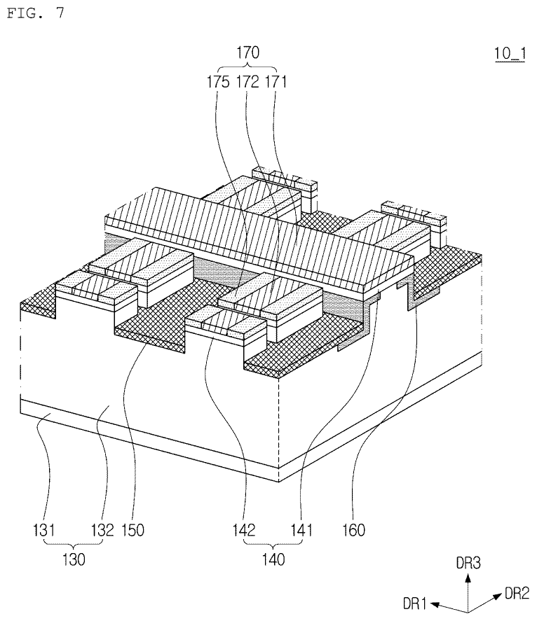

FIG. 7 is a view showing a semiconductor layer of a power semiconductor device according to another embodiment.

Referring to FIG. 7, a semiconductor layer of a power semiconductor device 10_1 according to the present embodiment differs from the semiconductor layer of the power semiconductor device 10 according to FIG. 2 in that the 1-2 source layer 172 may extend in the second direction.

Since the 1-2 source layer 172 may extend in the second direction DR2, an extension direction of the 1-2 source layer 172 and an extension direction of the 1-1 source layer 171 may intersect or be perpendicular. In the separated space, the side surfaces of the 1-2 source layer 172 may be exposed, and the exposed side surfaces of the 1-2 source layer 172 may be in direct contact with the insulating layer 190 (see FIG. 1).

Since the second source layer 175 may be disposed to extend in the second direction DR2, the current flowing through the second source layer 175 may also flow in the second direction DR2 in a plan view.

Since the remaining parts have been described above in FIG. 1, the detailed descriptions thereof will be omitted.

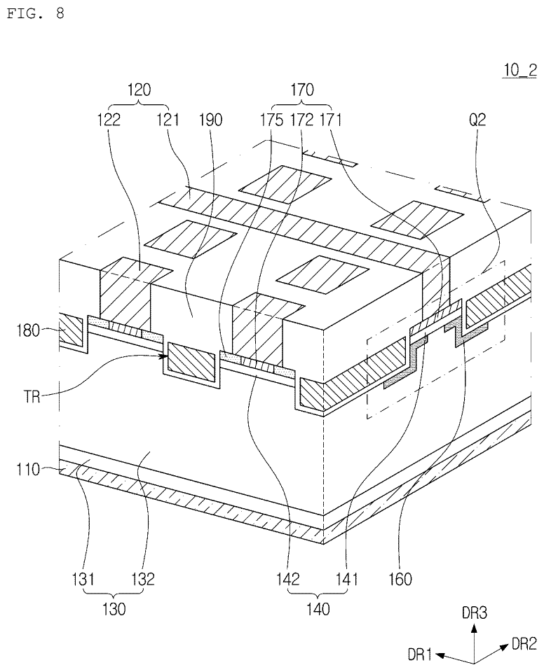

FIG. 8 is a view of the power semiconductor device according to another embodiment.

Referring to FIG. 8, a power semiconductor device 10_2 according to still another embodiment differs from the semiconductor device 10 according to FIG. 1 in that it does not include the protective layer 150 (see FIG. 1).

The upper surface of the bonding layer 160 may be disposed to overlap the lower surface of the 3-1 layer 141 and the lower surface of the insulating layer 190 surrounding the gate electrode 180 and may be in direct contact with the corresponding components 141 and 190.

The plurality of 2-1 electrodes 121 extending in the first direction DR1 may be disposed to be spaced apart from each other in the second direction DR2, and the plurality of gate electrodes 180 may be disposed between the 2-1 electrodes 121 spaced apart from each other, and since the plurality of gate electrodes 180 are disposed to surround the plurality of 2-1 electrodes 121 from all sides in a plan view, the bonding layer 160 disposed below the plurality of gate electrodes 180 may also extend in the first direction DR1.

Accordingly, even when the protective layer 150 (see FIG. 1) is not disposed, by adjusting a distance between the plurality of 2-1 electrodes 121, an electric field below the plurality of gate electrodes 180 may be adjusted by using only the bonding layer 160 and stabilized.

Since the remaining parts have been described above in FIG. 1, the detailed descriptions thereof will be omitted.

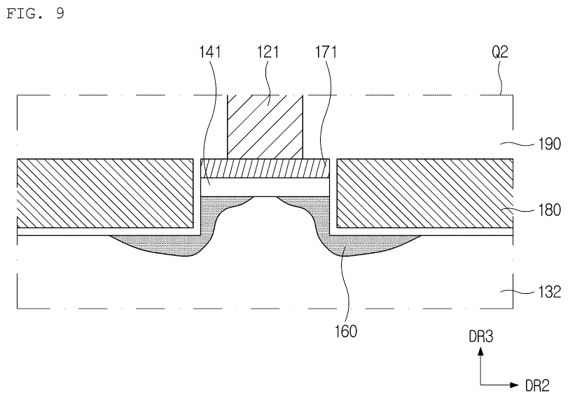

FIG. 9 is a cross-sectional view showing region Q2 of FIG. 8.

Referring to FIG. 9, the bonding layer 160 may be in direct contact with the lower portion of the 3-1 layer 141 and the lower portion and/or the side surfaces of the insulating layer 190 surrounding the gate electrode 180.

For example, the bonding layer 160 may be in contact with a portion of the lower portion of the 3-1 layer 141 and at the same time, may be in direct contact with only the side surfaces of the insulating layer 190 surrounding the gate electrode 180, and may be in contact with a portion of the lower portion of the 3-1 layer 141 and at the same time, may be in direct contact with the side surfaces and a portion of the lower surface of the insulating layer 190 surrounding the gate electrode 180.

The bonding layer 160 may be provided as a plurality of bonding layers, each of which may be disposed to be in direct contact with each of the plurality of insulating layers 190 surrounding the gate electrodes 180 that are spaced apart from each other in the second direction DR2. The plurality of bonding layers 160 may be in direct contact with each other, but may not be in direct contact with each other.

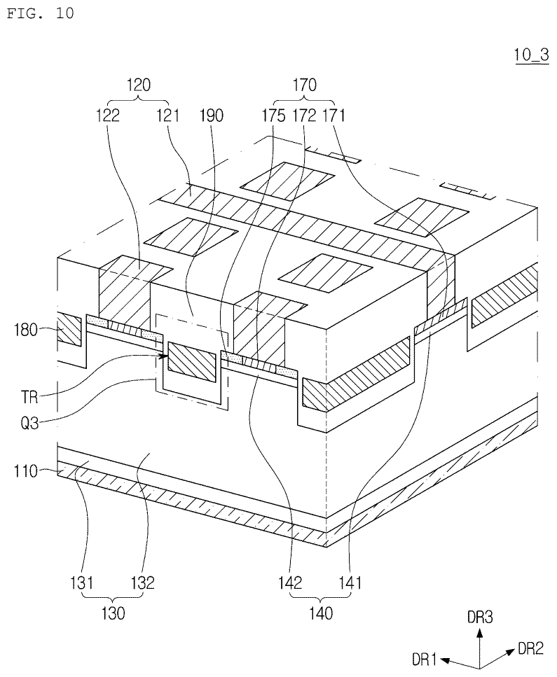

FIG. 10 is a view showing a power semiconductor device according to yet another embodiment.

Referring to FIG. 10, a power semiconductor device 10_3 according to the present embodiment differs from the semiconductor device 10_2 according to FIG. 8 in that the thickness of the insulating layer disposed below the gate electrode is larger than the thickness of the insulating layer disposed on the side surfaces of the gate electrode.

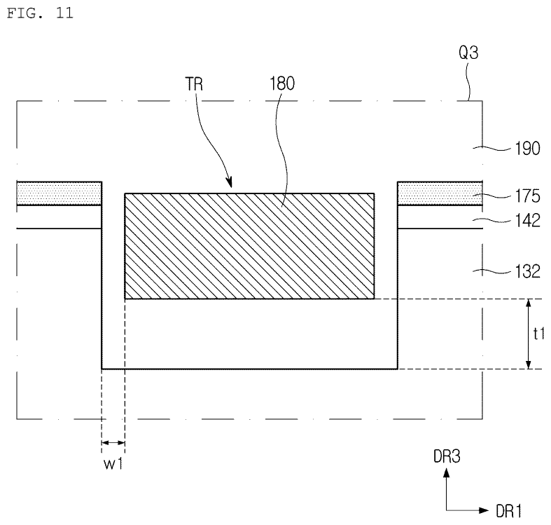

The insulating layer 190 may completely surround the gate electrode 180. When the thickness of the insulating layer 190 increases, the electric field may be dispersed while passing through the insulating layer 190, thereby increasing an electric field margin and improving the operational reliability of the power semiconductor device 10-3. However, as the thickness of the insulating layer 190 increases, the resistance of a channel formed in the 3-2 layer 142 by the gate electrode 180 may increase. Accordingly, when only the thickness of the insulating layer 190 disposed below the gate electrode 180 in which the channel is not formed (e.g., the other side in a third direction DR3) is formed thicker, it is possible to increase the electric field margin without increasing the resistance of the channel. The detailed description of the thickness of the insulating layer 190 will be described below in FIG. 11.

FIG. 11 is a cross-sectional view showing region Q3 of FIG. 10.

Referring to FIG. 11, the insulating layer 190 may completely surround the gate electrode 180. The insulating layer 190 disposed along the side surfaces of the gate electrode 180 may be in direct contact with the second source layer 175, the 3-2 layer 142, and the second layer 132 and may insulate each layer from the gate electrode 180.

When voltage is applied to the gate electrode 180, a channel may be formed along the region of the 3-2 layer 142 that is in contact with the insulating layer 190. Accordingly, electrons in the second layer 132 and the second source layer 175 may move through the channel formed in the 3-2 layer 142. In this case, when a width w1 of the insulating layer 190 in the first direction DR1 that is in contact with the 3-2 layer 142 increases, the resistance of the channel formed in the 3-2 layer 142 may increase.

On the other hand, the insulating layer 190 disposed below the gate electrode 180 may be in direct contact with only the second layer 132. Accordingly, even when voltage is applied to the gate electrode 180, a channel may not be formed below the gate electrode 180.

Accordingly, thicknesses of the insulating layer 190 disposed on the side surfaces of the gate electrode 180 and the insulating layer 190 disposed below the gate electrode 180 may need to be formed differently. That is, the insulating layer 190 disposed on the side surfaces of the gate electrode 180 may need to be formed thinly to minimize an increase in resistance of the channel, and the insulating layer 190 disposed under the gate electrode 180 may need to be formed thickly to increase the electric field margin, thereby improving the overall electrical and physical stability of the device.

For example, a thickness t1 of the insulating layer 190 disposed below the gate electrode 180 in the third direction DR3 may be larger than the width w1 of the insulating layer 190 disposed on the side surfaces of the gate electrode 180 in the first direction DR1. Accordingly, the resistance of the channel formed in the 3-2 layer 142 may not be increased, and at the same time, the electric field margin may be increased below the gate electrode 180.

A power semiconductor device according to various embodiments of the present specification may be described as follows.

According to various embodiments of the present specification, there is provided a power semiconductor device including a first electrode, a semiconductor layer on the first electrode, a second electrode on the semiconductor layer, and a plurality of gate electrodes on the semiconductor layer, wherein the semiconductor layer includes a first semiconductor layer of a first conductivity type on the first electrode, and a second semiconductor layer of a second conductivity type between the first semiconductor layer and the second electrode, the second semiconductor layer includes a 3-1 layer extending in a first direction, and a plurality of 3-2 layers spaced apart from each other in a second direction intersecting the first direction and spaced apart from the 3-1 layer in the second direction, the first semiconductor layer or the second semiconductor layer includes a trench region, the trench region is disposed around the plurality of 3-2 layers, the gate electrodes are disposed in the trench region, and the gate electrodes are disposed between the adjacent 3-1 and 3-2 layers and between a plurality of adjacent 3-2 layers.

According to the power semiconductor device according to various embodiments of the present specification, the plurality of 3-2 layers may be spaced apart from each other in the first direction.

According to the power semiconductor device according to various embodiments of the present specification, each of the plurality of 3-2 layers has a width in the first direction smaller than that of the 3-1 layer.

The power semiconductor device according to various embodiments of the present specification may further include a source layer, wherein the source layer may include a first source layer and a second source layer, and the first source layer and the second source layer may be disposed between the second semiconductor layer and the second electrode.

According to the power semiconductor device according to various embodiments of the present specification, the first source layer may have the second conductivity type, and a doping concentration of the first source layer may be higher than a doping concentration of the second semiconductor layer.

According to the power semiconductor device according to various embodiments of the present specification, the second source layer may have the first conductivity type, and a doping concentration of the second source layer may be higher than a doping concentration of the first semiconductor layer.

According to the power semiconductor device according to various embodiments of the present specification, the first source layer may be provided as a plurality of layers, and the plurality of first source layers may overlap the 3-1 layer and the 3-2 layer, respectively.

According to the power semiconductor device according to various embodiments of the present specification, the second source layer may surround at least a portion of the first source layer or completely surround the first source layer in a plan view.

According to the power semiconductor device according to various embodiments of the present specification, the first semiconductor layer and the second semiconductor layer may include silicon carbide (SiC).

According to the power semiconductor device according to various embodiments of the present specification, the first conductivity type may be an N type, and the second conductivity type may be a P type.

According to the power semiconductor device according to various embodiments of the present specification, the first semiconductor layer may include a first layer and a second layer on the first layer, and a doping concentration of the first layer may be higher than a doping concentration of the second layer.

The power semiconductor device according to various embodiments of the present specification may further include an insulating layer, wherein the insulating layer may surround the gate electrode.

According to the power semiconductor device according to various embodiments of the present specification, a thickness of the insulating layer below the gate electrode may be larger than a thickness at the side surfaces of the gate electrode.

According to the power semiconductor device according to various embodiments of the present specification, the insulating layer may surround the second electrode and expose a lower portion thereof.

The power semiconductor device according to various embodiments of the present specification may further include a bonding layer, wherein the bonding layer may be disposed between the first semiconductor layer and the second semiconductor layer.

According to the power semiconductor device according to various embodiments of the present specification, the bonding layer may be in direct contact with the first semiconductor layer, the second semiconductor layer, and the insulating layer disposed below the gate electrode.

According to the power semiconductor device according to various embodiments of the present specification, the bonding layer may be electrically connected to the second semiconductor layer.

According to the power semiconductor device according to various embodiments of the present specification, the bonding layer may have the second conductivity type.

The power semiconductor device according to various embodiments of the present specification may further include a protective layer, wherein the protective layer may be located between the bonding layer and the insulating layer.

According to the power semiconductor device according to various embodiments of the present specification, the protective layer may have the second conductivity type.

According to a power semiconductor device according to embodiments, by additionally arranging a protective layer and/or a bonding layer under a gate electrode and adjusting the electric field distribution under the gate electrode, thereby improving electrical and physical stability.

According to the power semiconductor device according to the embodiments, by increasing a density of a channel through a plurality of closed trench gate structures, it is possible to minimize an increase in resistance, thereby reducing energy loss.

However, effects obtainable from the present specification are not limited to the above-described effects, and other effects that are not mentioned will be able to be clearly understood by those skilled in the art to which the present specification pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

What is claimed is:

1. A power semiconductor device comprising:
a first electrode;
a semiconductor layer on the first electrode;
a second electrode on the semiconductor layer; and
a plurality of gate electrodes on the semiconductor layer,
wherein the semiconductor layer includes
a first semiconductor layer of a first conductivity type on the first electrode, and
a second semiconductor layer of a second conductivity type between the first semiconductor layer and the second electrode,
the second semiconductor layer includes
a 3-1 layer extending in a first direction, and
a plurality of 3-2 layers spaced apart from each other in a second direction intersecting the first direction and spaced apart from the 3-1 layer in the second direction,
the first semiconductor layer or the second semiconductor layer includes a trench region,
the trench region is disposed around the plurality of 3-2 layers,
the gate electrodes are disposed in the trench region, and
the gate electrodes are disposed between adjacent 3-1 and 3-2 layers and between a plurality of adjacent 3-2 layers.

2. The power semiconductor device of claim 1, wherein the plurality of 3-2 layers are spaced apart from each other in the first direction.

3. The power semiconductor device of claim 1, wherein each of the plurality of 3-2 layers has a width in the first direction smaller than that of the 3-1 layer.

4. The power semiconductor device of claim 1, further comprising a source layer, wherein the source layer includes a first source layer and a second source layer, and the first source layer and the second source layer are disposed between the second semiconductor layer and the second electrode.

5. The power semiconductor device of claim 4, wherein the first source layer has the second conductivity type, and a doping concentration of the first source layer is higher than a doping concentration of the second semiconductor layer.

6. The power semiconductor device of claim 4, wherein the second source layer has the first conductivity type, and a doping concentration of the second source layer is higher than a doping concentration of the first semiconductor layer.

7. The power semiconductor device of claim 4, wherein the first source layer is provided as a plurality of layers, and the plurality of first source layers overlap the 3-1 layer and the 3-2 layer, respectively.

8. The power semiconductor device of claim 4, wherein the second source layer surrounds at least a portion of the first source layer or completely surrounds the first source layer in a plan view.

9. The power semiconductor device of claim 1, wherein the first semiconductor layer and the second semiconductor layer include silicon carbide (SiC).

10. The power semiconductor device of claim 1, wherein the first conductivity type is an N type and the second conductivity type is a P type.

11. The power semiconductor device of claim 1, wherein the first semiconductor layer includes a first layer and a second layer on the first layer, and a doping concentration of the first layer is higher than a doping concentration of the second layer.

12. The power semiconductor device of claim 1, further comprising an insulating layer, wherein the insulating layer surrounds the gate electrode.

13. The power semiconductor device of claim 12, wherein a thickness of the insulating layer below the gate electrode is larger than a thickness at side surfaces of the gate electrode.

14. The power semiconductor device of claim 12, wherein the insulating layer surrounds the second electrode and exposes a lower portion thereof.

15. The power semiconductor device of claim 12, further comprising a bonding layer, wherein the bonding layer is disposed between the first semiconductor layer and the second semiconductor layer.

16. The power semiconductor device of claim 15, wherein the bonding layer is in direct contact with the first semiconductor layer, the second semiconductor layer, and the insulating layer disposed below the gate electrode.

17. The power semiconductor device of claim 15, wherein the bonding layer is electrically connected to the second semiconductor layer.

18. The power semiconductor device of claim 15, wherein the bonding layer has the second conductivity type.

19. The power semiconductor device of claim 15, further comprising a protective layer, wherein the protective layer is located between the bonding layer and the insulating layer.

20. The power semiconductor device of claim 19, wherein the protective layer has the second conductivity type.
